(19) United States
(12) Patent Application Publication
(10) Pub. No.: US 2025/0391741 A1
(43) Pub. Date: Dec. 25, 2025

(54) PACKAGE STRUCTURE, STACKED PACKAGE STRUCTURE, AND PACKAGING METHOD

(71) Applicant: JCET GROUP CO., LTD., Jiangsu Province, (CN)

(72) Inventors: Zhengyang Sun, Jiangsu Province (CN); Kaiyuan Yu, Jiangsu Province (CN); Chang Chen, Jiangsu Province (CN)

(73) Assignee: JCET GROUP CO., LTD., Jiangsu Province (CN)

(21) Appl. No.: 19/246,423

(22) Filed: Jun. 23, 2025

(30) Foreign Application Priority Data
Jun. 24, 2024 (CN) 202410822407.6

(51) Int. Cl. H01L 23/49; H01L 23/00; H01L 23/31; H01L 25/10

(52) U.S. Cl. CPC H01L 23/49; H01L 23/3107; H01L 24/48; H01L 25/10; H01L 2224/48245; H01L 2225/1058

(57) ABSTRACT

Provided are a package structure, a stacked package structure, and a packaging method. leads in the package structure are spaced apart around a base island. Connecting posts are located on the leads and are connected to the leads, and end surfaces, which face away from a chip, of the connecting posts are provided with lateral grooves. A plastic packaging layer is filled between the connecting posts and in the lateral grooves, and the plastic packaging layer further exposes the end surfaces, which face away from the chip, of the connecting posts. Through the end surfaces, which are exposed from the plastic packaging layer, of the connecting posts, the package structure can be electrically connected to another circuit component from a side surface, thereby providing various connection forms.

### CROSS-REFERENCE TO RELATED APPLICATION

This application claims the benefit of priority under 35 U.S.C. § 119 from Chinese Patent Application No. 202410822407.6, filed on Jun. 24, 2024, the entire disclosure of which is hereby incorporated herein by reference.

### TECHNICAL FIELD

Embodiments of the present invention relate to the field of semiconductor packaging, and in particular, to a package structure, a stacked package structure, and a packaging method.

### BACKGROUND

Semiconductor package technologies include many package forms. With a trend of miniaturization and thinning of a chip package structure, a quad flat no-lead (QFN) package that pertains to a flat package series is developed. Because the quad flat no-lead package has no leads extending outward, the dimension thereof can be greatly reduced, and the quad flat no-lead package has a short signal transmission path and a relatively high signal transmission speed. Therefore, the quad flat no-lead package is applicable to high-speed and high-frequency products with a medium or low lead count, and has become a mainstream package form.

A bottom surface of the quad flat no-lead package includes a base island and leads. The base island is located at a center of the bottom surface and is exposed on the bottom surface, and the base island is configured to conduct heat. The leads surround a periphery of the base island and are configured for electrical connection. In addition, a chip packaged in the quad flat no-lead package is bonded to the base island.

Components packaged in the form of a quad flat no-lead package may be collectively referred to as QFN package devices. During operation, heat generated by a package device in the form of a quad flat no-lead package causes a temperature of the package device to rise. When the temperature exceeds a certain limit, normal operational performance of a chip is affected. Therefore, heat dissipation performance of the package device in the form of the quad flat no-lead package needs to be improved. In addition, an improvement is sought for a manner in which the QFN package device is connected to another circuit component.

### SUMMARY

Against the problems to be solved by embodiments of the present invention, a package structure, a stacked package structure, and a packaging method are provided, to provide various connection forms while improving a heat dissipation capability of the package structure.

To solve the above-mentioned problems, an embodiment of the present invention provides a package structure, including: a base island; leads spaced apart around the base island; a chip located on the base island and electrically connected to the leads; connecting posts located on the leads and connected to the leads, where end surfaces, which face away from the chip, of the connecting posts are provided with lateral grooves; and a plastic packaging layer covering the chip, the leads, and the base island, where the plastic packaging layer is filled between the connecting posts and in the lateral grooves, and the plastic packaging layer further exposes tops of the connecting posts and the end surfaces, which face away from the chip, of the connecting posts.

Optionally, the end surfaces, which face away from the chip, of the connecting posts are flush with side walls of the leads in a vertical direction.

Optionally, the plastic packaging layer further exposes tops of the connecting posts.

Optionally, tops of the end surfaces, which face away from the chip, of the connecting posts each have a step.

Optionally, a cross section of the base island is trapezoidal, and each of the leads is invertedly trapezoidal.

Optionally, the package structure further includes: wires for connecting the chip to the leads.

An embodiment of the present invention provides a stacked package structure, including: at least two package structures arranged in a stacked manner, where one or more of the package structures each are the aforementioned package structure.

Optionally, the package structures each are the aforementioned package structure, and connecting posts in different package structures are connected.

Optionally, the stacked package structure includes: a first package structure, where the first package structure is the aforementioned package structure; and a second package structure, where the second package structure is different from the first package structure, and the second package structure includes: exposed leads, where the leads are connected to connecting posts in a first package structure.

An embodiment of the present invention further provides a packaging method, including: providing a frame, where the frame includes a base island, and conductive structures spaced apart from the base island; attaching a chip to the base island; providing hollow rectangular structures, where a through-hole is formed in each of the hollow rectangular structures; attaching each of the hollow rectangular structures to one conductive structure; forming a plastic packaging layer covering the chip, the base island, and the conductive structures, where the plastic packaging layer is further filled between the hollow rectangular structures and in the through-holes of the hollow rectangular structures; and segmenting the hollow rectangular structure, the plastic packaging layer, and the conductive structure at the through-hole, to form spaced leads and connecting posts located on the leads, where lateral grooves are formed in side surfaces, which face away from the chip, of the connecting posts, and the plastic packaging layer is filled in the lateral grooves and exposes tops of the connecting posts and end surfaces, which face away from the chip, of the connecting posts.

Optionally, each of the hollow rectangular structures is attached to one conductive structure by a metal bonding process, a surface mount technology, or an adhesive process.

Optionally, the step of providing hollow rectangular structures includes: manufacturing a stamping mold; providing a metal sheet; placing the metal sheet in the stamping mold; and stamping the metal sheet to form the hollow rectangular structures, or the step of providing hollow rectangular structures includes: providing a cuboid structure, where the cuboid structure is made of a metal; and etching the cuboid structure by a dry etching process, to form the hollow rectangular structures.

Optionally, the step of segmenting the hollow rectangular structure and the conductive structure includes: segmenting the hollow rectangular structure and the conductive structure by a cutting knife, a laser, or a plasma etching process.

Optionally, in the step of segmenting the hollow rectangular structure and the conductive structure, the end surfaces, which face away from the chip, of the connecting posts are flush with side walls of the leads in a vertical direction.

Optionally, in the step of providing hollow rectangular structures, each of the hollow rectangular structures has an opening in communication with one through-hole; in the step of attaching each of the hollow rectangular structures to one conductive structure, the opening is located at an end, which faces away from the conductive structure, of the hollow rectangular structure; and the step of segmenting the hollow rectangular structure, the plastic packaging layer, and the conductive structure includes: segmenting the hollow rectangular structure, the plastic packaging layer, and the conductive structure along the opening by a cutting knife, a laser, or a plasma etching process.

Optionally, the packaging method further includes: etching, after the attaching each of the hollow rectangular structures to one conductive structure, an end surface, which face away from the conductive structure, of the hollow rectangular structure, to form a non-through groove structure; and the step of segmenting the hollow rectangular structure, the plastic packaging layer, and the conductive structure includes: segmenting the hollow rectangular structure and the conductive structure along the groove structure by a cutting knife, a laser, or a plasma etching process.

Optionally, the step of etching an end surface, which face away from the conductive structure, of the hollow rectangular structure, to form a groove structure includes: etching the end surface, which face away from the conductive structure, of the hollow rectangular structure, to form a non-through first groove; and etching a partial region of a bottom of the first groove to form a second groove, the second groove and the first groove forming the groove structure; and the step of segmenting the hollow rectangular structure, the plastic packaging layer, and the conductive structure includes: segmenting the hollow rectangular structure, the plastic packaging layer, and the conductive structure along the second groove by a cutting knife, a laser, or a plasma etching process, and forming steps at tops of the end surfaces, which face away from the chip, of the connecting posts.

Optionally, in the step of etching a partial region of a bottom of the first groove, the second groove is formed at a center of the bottom of the first groove.

Optionally, in the step of segmenting the hollow rectangular structure, the plastic packaging layer, and the conductive structure, segmentation is performed along a center of the hollow rectangular structure.

Optionally, the step of forming a plastic packaging layer covering the chip, the base island, the conductive structures, and the hollow rectangular structures includes: forming a plastic packaging material layer covering the chip, the base island, the conductive structures, and the hollow rectangular structures; and planarizing the plastic packaging material layer, with tops of the hollow rectangular structures as planarization positions, to form the plastic packaging layer.

Optionally, in the step of providing a frame, a cross section of the base island is trapezoidal, and each of the conductive structures is invertedly trapezoidal; and each of the leads is invertedly trapezoidal after the hollow rectangular structure, the plastic packaging layer, and the conductive structure are segmented.

Compared with the prior art, the technical solutions in the embodiments of the present invention have the following advantages.

In the package structure according to the embodiment of the present invention, the leads are spaced apart from the base island. The connecting posts are located on the leads and are connected to the leads, and the end surfaces, which face away from the chip, of the connecting posts are provided with the lateral grooves. The plastic packaging layer is filled between the connecting posts and in the lateral grooves, and the plastic packaging layer further exposes the end surfaces, which face away from the chip, of the connecting posts. Through the end surfaces, which are exposed from the plastic packaging layer, of the connecting posts, the package structure can be electrically connected to another circuit component from a side surface, thereby providing various connection forms. In addition, the tops of the connecting posts and the base island are exposed from two opposite surfaces of the plastic packaging layer respectively, so that the base island can dissipate heat upward by mounting the tops of the connecting posts on a PCB subsequently. Furthermore, a heat sink may be arranged on the base island to further improve the heat dissipation capability of the base island.

### BRIEF DESCRIPTION OF THE DRAWINGS

FIG. 1 to FIG. 6B are schematic structural diagrams corresponding to steps of a packaging method according to Embodiment 1 of the present invention;

FIG. 7 to FIG. 9 are schematic structural diagrams corresponding to steps of a packaging method according to Embodiment 2 of the present invention;

FIG. 10 to FIG. 14 are schematic structural diagrams corresponding to steps of a packaging method according to Embodiment 3 of the present invention;

FIG. 15 and FIG. 16 are schematic structural diagrams of a stacked package structure according to Embodiment 1 of the present invention; and

FIG. 17 is a schematic structural diagram of a stacked package structure according to Embodiment 2 of the present invention.

### DETAILED DESCRIPTION

From the background, currently, it can be learned that components currently packaged in the form of a quad flat no-lead package may be collectively referred to as QFN package devices. During operation, heat generated by a package device in the form of a quad flat no-lead package causes a temperature of the package device to rise. When the temperature exceeds a certain limit, normal operational performance of a chip is affected. Therefore, heat dissipation performance of the package device in the form of the quad flat no-lead package needs to be improved. In addition, an improvement is sought for a manner in which the QFN package device is connected to another circuit component.

To solve the technical problems, in a package structure according to an embodiment of the present invention, leads are spaced apart from a base island. Connecting posts are located on the leads and are connected to the leads, and end surfaces, which face away from a chip, of the connecting posts are provided with lateral grooves. A plastic packaging layer is filled between the connecting posts and in the lateral grooves, and the plastic packaging layer further exposes the end surfaces, which face away from the chip, of the connecting posts. Through the end surfaces, which are exposed from the plastic packaging layer, of the connecting posts, the package structure can be electrically connected to another circuit component from a side surface, thereby providing various connection forms. In addition, because the connecting posts are located on the leads and are connected to the leads, and the plastic packaging layer further exposes the end surfaces, which face away from the chip, of the connecting posts, heat from the leads can be transmitted out through the end surfaces of the connecting posts. Compared with a package structure in which heat is dissipated only through a base island, the package structure according to an embodiment of the present invention increases a heat dissipation path through the end surfaces of the connecting posts, thereby improving a heat dissipation capability of the package structure. In addition, the tops of the connecting posts and the base island are exposed from two opposite surfaces of the plastic packaging layer respectively, so that the base island can dissipate heat upward by mounting the tops of the connecting posts on a PCB subsequently. Furthermore, a heat sink may be arranged on the base island to further improve the heat dissipation capability of the base island.

To make the foregoing objectives, features, and advantages of the embodiments of the present invention more apparent and easier to understand, specific embodiments of the present invention are described in detail below with reference to the accompanying drawings.

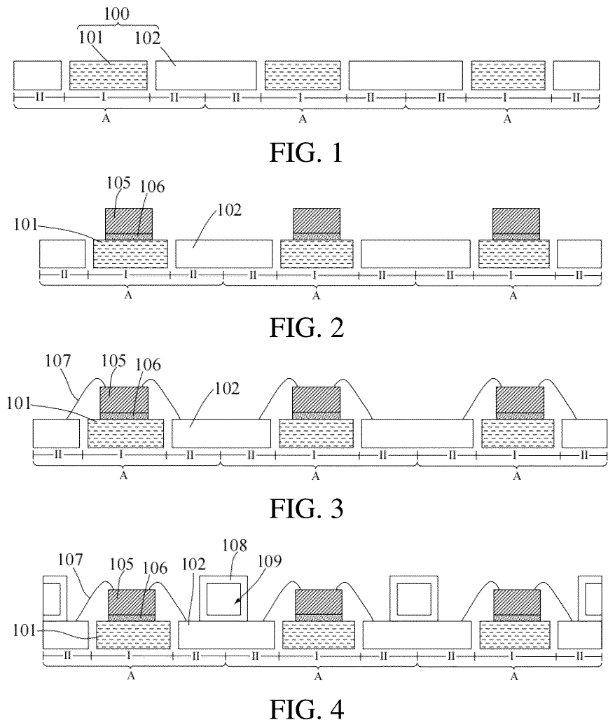

Correspondingly, the present invention further provides a packaging method. FIG. 1 to FIG. 6B are schematic structural diagrams corresponding to steps of a packaging method according to Embodiment 1 of the present invention.

Referring to FIG. 1, a frame 100 is provided. The frame 100 includes a base island 101, and conductive structures 102 spaced apart around the base island 101.

The frame 100 is used as a carrier for packaging a subsequent chip.

In this embodiment, according to the packaging method, packaging is performing in a form of a quad flat no-lead (QFN) package. In a subsequent packaging process, the conductive structure 102 is segmented into leads.

The base island 101 has good heat dissipation performance, and the conductive structures 102 have good electrical conductivity.

In this embodiment, the base island 101 and the conductive structures 102 are made of the same material, which includes, but is not limited to, one or more of gold, copper, nickel, and tin.

The frame 100 includes a plurality of component regions A. The component regions A are configured to prepare a single package structure.

The component regions A each include a first region I and second regions II located around the first region I. The base island 101 is located in the first region I, and the conductive structures 102 are located in the second regions II of two adjacent component regions A. That is, the conductive structures 102 span boundaries between adjacent component regions A.

It should be noted that, in a subsequent packaging process, after each of the conductive structures 102 is segmented, spaced leads are formed and different leads are located in different component regions A.

In this embodiment, the first region I is located at a center of the component regions A. In another embodiment, the first region I may alternatively be biased to be located on a side of the component region A according to different process layouts.

It should be further noted that, boundaries between adjacent component regions A correspond to centers of the conductive structures 102. Subsequently, when segmentation is performed along the centers of the conductive structures 102, segmentation is performed along boundaries between adjacent component regions A.

In this embodiment, a cross section of the base island 101 is rectangular, and a cross section of each of the conductive structures 102 is rectangular. In another embodiment, a cross section of the base island may alternatively be trapezoidal, and a cross section of each of the conductive structures may be invertedly trapezoidal.

Referring to FIG. 2, a chip 105 is attached to the base island 101.

The chip 105 is attached to the base island 101, so that during operation of a subsequently formed package structure, heat generated by the chip 105 is dissipated out through the base island 101, to reduce a temperature of the chip 105, so that the chip 105 operates normally.

In this embodiment, the chip 105 is attached to the base island 101 by an adhesive film 106. The adhesive film 106 includes a die bonding film (e.g., Die Attach Film, DAF). The die bonding film has good adhesion, and can simplify a packaging process and improve manufacturing efficiency. In another embodiment, the chip may alternatively be formed on the base island by a surface mount technology (SMT).

In this embodiment, an electrical connection end of the chip 105 is located at a top of the chip 105. In another embodiment, the electrical connection end of the chip may alternatively be located on a side wall of the chip.

Referring to FIG. 3, end portions of the conductive structures 102 are connected to the chip 105 by wires 107.

The wires 107 are configured to electrically connect the chip 105 to the conductive structures 102.

In this embodiment, the conductive structures 102 are electrically connected to the chip 105 by a wire bonding process.

In this embodiment, the wires 107 each are a conductive wire, and the wires 107 are made of a material including gold, copper, or aluminum. Correspondingly, the wires 107 each may be a gold wire, a copper wire, or an aluminum wire.

In a subsequent packaging process, each of the conductive structures 102 is segmented at the center of the conductive structure 102.

In this embodiment, connections are performed between end portions of the conductive structures 102 and the wires 107. Therefore, damage to the wires 107 can be avoided in a subsequent process of segmenting the conductive structures 102.

Because an electrical connection end of the chip 105 is located at the top of the chip 105, correspondingly, the wires 107 electrically connects the conductive structures 102 to the electrical connection end of the top of the chip 105. In another embodiment, because an electrical connection end of the chip is located on a side wall of the chip, the wires electrically connect the conductive structures to the electrical connection end of the side wall of the chip.

In this embodiment, end portions of the conductive structures 102 are close to the chip 105, so that the wires 107 each have a small length, and the conductive structures 102 are segmented into leads in a subsequent packaging process. Therefore, the wires 107 each have a small length, which reduces parasitic resistance between the leads and the chip 105.

Referring to FIG. 4, the packaging method further includes the following step. Hollow rectangular structures 108 are provided, where a through-hole 109 is formed in each of the hollow rectangular structures 108.

In this embodiment, the through-hole 109 runs through two corresponding end surfaces of the hollow rectangular structure 108.

In this embodiment, the step of forming hollow rectangular structures 108 includes a stamping process. Specifically, the step of forming hollow rectangular structures 108 includes: manufacturing a stamping mold; providing a metal sheet; placing the metal sheet in the stamping mold; and stamping the metal sheet to form the hollow rectangular structures 108.

In another embodiment, the step of providing hollow rectangular structures 108 includes a dry etching process. Specifically, a cuboid structure is provided; and the cuboid structure is etched by the dry etching process, to form the hollow rectangular structures 108.

In this embodiment, the cuboid structure is made of a metal having good thermal conductivity and electrical conductivity.

It should be noted that, the hollow rectangular structures 108 each have a wall thickness greater than 0.1 mm. In a subsequent packaging process, the hollow rectangular structure 108 is segmented to form connecting posts. End surfaces, which face away from the chip 105, of the connecting posts each are configured to be connected to another circuit component or to dissipate heat. The wall thicknesses of the hollow rectangular structures 108 directly determine areas of the end surfaces, which face away from the chip 105, of the connecting posts. In this case, if the hollow rectangular structures 108 each have a smaller wall thickness, the end surfaces, which face away from the chip 105, of the connecting posts have a poor heat dissipation effect, and the end surfaces, which face away from the chip 105, of the connecting posts each have large contact resistance with another circuit component.

Still referring to FIG. 4, each of the hollow rectangular structures 108 is attached to one conductive structure 102.

As each of the hollow rectangular structures 108 is attached to one conductive structure 102, preparation is made for segmenting the hollow rectangular structure 108 into connecting posts in a subsequent packaging process.

In this embodiment, each of the hollow rectangular structures 108 is attached to one conductive structure 102 by a surface mount technology. In another embodiment, each of the hollow rectangular structures may alternatively be attached to one conductive structure by a metal bonding process or an adhesive process.

In this embodiment, the hollow rectangular structure 108 is attached to a center of the conductive structure 102, so that the hollow rectangular structure 108 does not cover the wire 107 on the end portion of the conductive structure 102, and depress wire of the wire 107 can be avoided.

It should be noted that, the hollow rectangular structure 108 spans different component regions A, so that after the hollow rectangular structure 108 is subsequently segmented, connecting posts are formed in the different component regions A.

It should be further noted that, in this embodiment, the chip 105 is first arranged, and then the hollow rectangular structures 108 are arranged. In another embodiment, alternatively, the hollow rectangular structures may be arranged first, and then the chip may be arranged.

Referring to FIG. 5, a plastic packaging layer 110 covering the chip 105, the base island 101, and the conductive structures 102 is formed. The plastic packaging layer 110 is further filled between the hollow rectangular structures 108 and in the through-holes 109 of the hollow rectangular structures 108.

The plastic packaging layer 110 is configured to package the chip 105, the base island 101, the conductive structures 102, and the hollow rectangular structures 108 together, to provide good protection to the chip 105, the base island 101, the conductive structures 102, and the hollow rectangular structures 108.

In this embodiment, the plastic packaging layer 110 may be made of filler-containing epoxy resin, polyimide resin, benzocyclobutene resin, or polybenzoxazole resin, or may be made of filler-containing polybutylene terephthalate, polycarbonate, polyethylene terephthalate, polyethylene, polypropylene, polyolefin, polyurethane, polyolefin, polyethersulfone, polyamide, polyurethane, ethylene-vinyl acetate copolymer, or polyvinyl alcohol. In an embodiment, the filler may be an inorganic filler or an organic filler.

It should be noted that, in a process of forming the plastic packaging layer 110, the plastic packaging layer 110 covers the wires 107, so that the wires 107 are not exposed outside the plastic packaging layer 110, thereby preventing a subsequently formed package structure from being bridged or short-circuited with another circuit element due to the exposed wires 107.

In this embodiment, the step of forming a plastic packaging layer 110 includes: forming a plastic packaging material layer covering the wires 107, the chip 105, the base island 101, the hollow rectangular structures 108, and the conductive structures 102; and planarizing the plastic packaging material layer, with tops of the hollow rectangular structures 108 as planarization positions, to form the plastic packaging layer 110.

In this embodiment, the plastic packaging material layer is formed by a transfer molding process. The transfer molding process can precisely control a usage amount of a plastic packaging material, to reduce a material waste, can provide uniform material distribution, and can ensure that there is no defect such as bubbles in the plastic packaging material layer, thereby improving reliability of the package structure.

In this embodiment, the plastic packaging material layer is planarized by a grinding process. In another embodiment, the plastic packaging material layer may alternatively be planarized by a chemical-mechanical planarization (CMP) process.

It should be noted that, the plastic packaging layer 110 exposes the tops of the hollow rectangular structures 108, and after the hollow rectangular structures 108 are segmented to form connecting posts, tops 115 of corresponding connecting posts are also exposed at the top of the plastic packaging layer 110.

Referring to FIGS. 6A and 6B, there are a plurality of package structures in FIG. 6A, and FIG. 6B shows only one package structure. The hollow rectangular structure 108, the plastic packaging layer 110, and the conductive structure 102 are segmented at the through-hole 109, to form two spaced leads 112 and connecting posts 111 located on the leads 112. Lateral grooves 114 are formed in side surfaces, which face away from the chip 105, of the connecting posts 111, and the plastic packaging layer 110 is filled in the lateral grooves 114 and exposes tops of the connecting posts 111 and end surfaces 113, which face away from the chip 105, of the connecting posts 111.

In the packaging method according to the embodiment of the present invention, a through-hole 109 is formed in each of the provided hollow rectangular structures 108, and in the step of forming a plastic packaging layer 110, the plastic packaging layer 110 covers the chip 105, the conductive structures 102, and the base island 101, and the plastic packaging layer 110 is further filled between the hollow rectangular structures 108 and in the through-holes 109 of the hollow rectangular structures 108. In the step of segmenting the hollow rectangular structure 108, the plastic packaging layer 110, and the conductive structure 102 at the through-hole 109, end surfaces 113, which face away from the chip 105, of the formed connecting posts 111 are exposed from the plastic packaging layer 110. The connecting posts 111 are connected to the leads 112, so that the end surfaces 113, which face away from the chip 105, of the connecting posts 111 are exposed from the plastic packaging layer 110, so that heat generated by the leads 112 can be transmitted out. Compared with a package structure in which heat is dissipated only by a thermally conductive pad, the packaging method according to the embodiment of the present invention increases a heat dissipation path through the end surfaces 113 of the connecting posts, thereby improving the heat dissipation capability of the package structure. In addition, since the end surfaces 113, which face away from the chip 105, of the connecting posts 111 are exposed from the plastic packaging layer 110, the package structure can be electrically connected to another circuit component from a side surface, thereby providing various connection forms.

The plastic packaging layer 110 further exposes tops 115 of the connecting posts 111, thereby facilitating an electrical connection between the package structure and another circuit component through the tops 115 of the connecting posts 111 in a subsequent process. In addition, the tops 115 of the connecting posts 111 and the base island 101 are exposed from two opposite surfaces of the plastic packaging layer 110 respectively, so that the base island can dissipate heat upward by mounting the tops 115 of the connecting posts 111 on a PCB subsequently. Furthermore, a heat sink may be arranged on the base island to further improve the heat dissipation capability of the base island.

It should be noted that, in addition to that the end surfaces 113, which face away from the chip 105, of the connecting post 111 are exposed on a side wall of the plastic packaging layer 110, side walls of the leads 112 are further exposed. In a subsequent packaging process, when another circuit component needs to be connected from the side surface of the package structure, there are a plurality of optional connection points, thereby having various connection forms.

It should be further noted that, the side walls of the leads 112 and the end surfaces 113 of the bottoms of the connecting posts 111 are connected into pieces, which each have a relatively large area and provide a relatively large soldering surface located on the side surface, thereby improving soldering reliability.

In this embodiment, in the step of forming a plastic packaging layer 110, the plastic packaging layer 110 exposes the tops of the hollow rectangular structures 108. Therefore, in the step of segmenting the hollow rectangular structures 108, the plastic packaging layer 110 further exposes the tops 115 of the connecting posts 111. The plastic packaging layer 110 exposes the tops 115 of the connecting posts 111, thereby facilitating an electrical connection between the package structure and another circuit component through the tops 115 of the connecting posts 111 in a subsequent process. In addition, the tops 115 of the connecting posts 111 and the base island 101 are exposed from two opposite surfaces of the plastic packaging layer 110 respectively, so that the base island can dissipate heat upward by mounting the tops 115 of the connecting posts 111 on a PCB subsequently. Furthermore, a heat sink may be arranged on the base island to further improve the heat dissipation capability of the base island.

In this embodiment, the hollow rectangular structures 108, the plastic packaging layer 110, and the conductive structures 102 are segmented, so that package structures in the component regions A are separated.

In this embodiment, the hollow rectangular structures 108, the plastic packaging layer 110, and the conductive structures 102 are segmented by a cutting knife. Segmentation by the cutting knife helps improve segmentation efficiency and reduce production costs. In another embodiment, the hollow rectangular structures, the plastic packaging layer, and the conductive structures may alternatively be segmented by a plasma etching process or a laser cutting process.

It should be noted that, in the step of segmenting the hollow rectangular structures 108, the plastic packaging layer 110, and the conductive structures 102, segmentation is performed along centers of the hollow rectangular structures 108. This enables connecting posts 111 formed on different leads 112 to be the same in size.

In this embodiment, the hollow rectangular structures 108 and the conductive structures 102 are segmented in the same step. Therefore, the end surfaces 113, which face away from the chip 105, of the connecting posts 111 are flush with side walls of the leads 112 in a vertical direction.

It should be further noted that, the leads 112 after the segmentation are located around the base island 101.

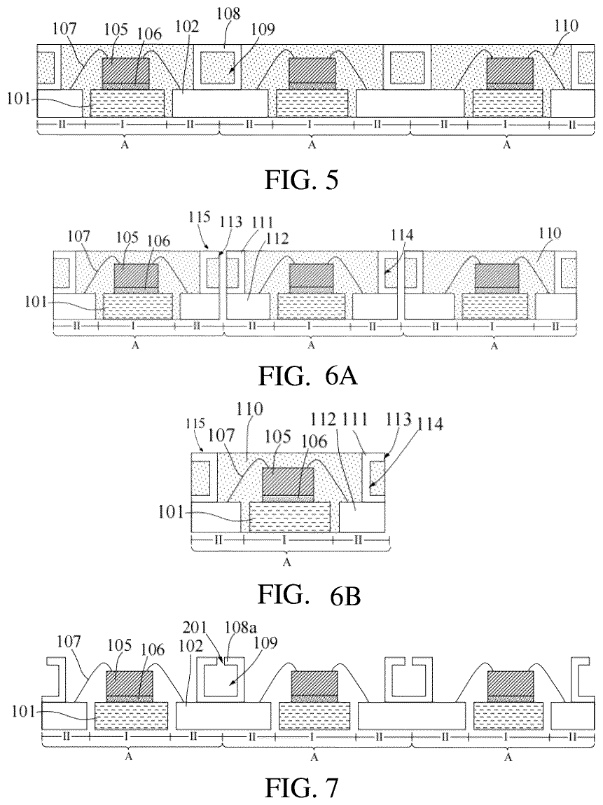

Referring to FIG. 7 to FIG. 9, FIG. 7 to FIG. 9 are schematic structural diagrams corresponding to steps of a packaging method according to Embodiment 2 of the present invention.

Similarities between this embodiment of the present invention and Embodiment 1 are not repeated herein, but differences are as follows.

As shown in FIG. 7, in the step of providing hollow rectangular structures 108a, each of the hollow rectangular structures 108a has an opening 201 in communication with one through-hole 109. In a subsequent packaging process, the hollow rectangular structure 108a is segmented, and the opening 201 helps reduce difficulty in segmenting the hollow rectangular structure 108a, thereby reducing difficulty in segmenting the package structure.

In the step of attaching each of the hollow rectangular structures 108a to one conductive structure 102, the opening 201 is located on an end surface, which faces away from the conductive structure 102, of the hollow rectangular structure 108a. In a subsequent packaging process, when segmentation is performed by a cutting knife, a cutting direction is perpendicular to a surface of the conductive structure 102. The opening 201 is located at an end, which faces away from the conductive structure 102, of the hollow rectangular structure 108a, and the opening 102 overlaps a cutting line, to provide a segmentation mark for the cutting knife, thereby reducing difficulty in segmenting the hollow rectangular structure 108a, the plastic packaging layer 110, and the conductive structure 102.

It should be noted that, the opening 201 has an extension direction, the extension direction of the opening 201 is the same as the extension direction of the through-hole 109, and the opening 201 runs through a top surface of the hollow rectangular structure 108a in the extension direction of the opening. In another embodiment, alternatively, there may be a plurality of spaced openings, and each of the openings extends along an extension direction of one through-hole.

As shown in FIG. 8, in the step of forming the plastic packaging layer 110, the plastic packaging layer 110 fills the openings 210.

As shown in FIG. 9, the step of segmenting the hollow rectangular structure 108a, the plastic packaging layer 110, and the conductive structure 102 includes: segmenting the hollow rectangular structure 108a, the plastic packaging layer 110, and the conductive structure 102 along the opening 201 by a cutting knife.

The opening 201 provides a segmentation mark, thereby reducing difficulty in segmenting the hollow rectangular structure 108a, the plastic packaging layer 110, and the conductive structure 102.

Specifically, the hollow rectangular structure 108a is segmented into spaced connecting posts 111a, and lateral grooves 114a are formed in side surfaces, which face away from the chip 105, of the connecting posts 111a; and the conductive structure 102 is segmented into spaced leads 112; and the plastic packaging layer 110 originally located in the through-hole 109 is segmented, the segmented plastic packaging layers 110 are respectively located in the lateral grooves 114a of the spaced connecting posts 111a, and end surfaces 113, which face away from the chip 105, of the connecting posts 111 are exposed outside the plastic packaging layer 110.

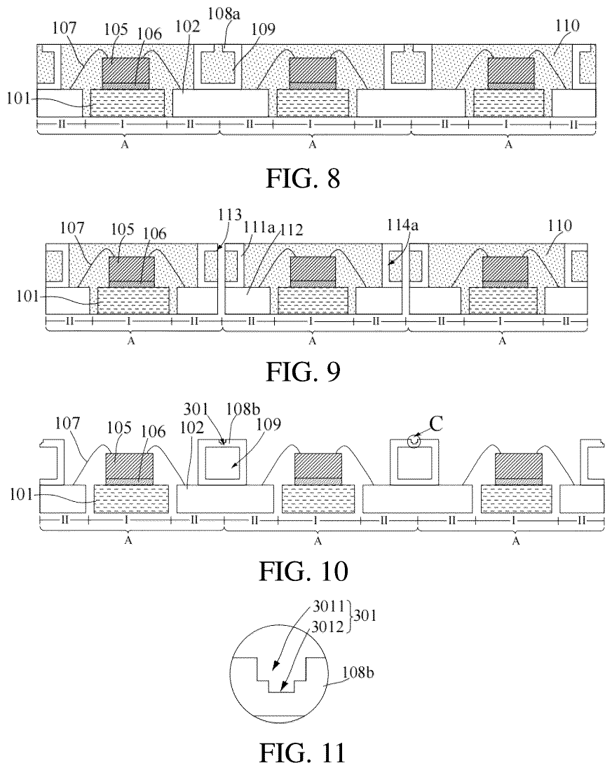

Referring to FIG. 10 to FIG. 14, FIG. 10 to FIG. 14 are schematic structural diagrams corresponding to steps of a packaging method according to Embodiment 3 of the present invention.

Similarities between this embodiment of the present invention and Embodiment 1 are not repeated herein, but differences are as follows.

The packaging method further includes: etching, after each of the hollow rectangular structures 108b is formed on one conductive structure 102, an end surface, which face away from the conductive structure 102, of the hollow rectangular structure 108b, to form a non-through groove structure 301 (as shown in FIG. 11). In a subsequent packaging process, the hollow rectangular structure 108b is segmented, and the groove structure 301 reduces difficulty in segmenting the hollow rectangular structure 108b.

In a subsequent packaging process, when segmentation is performed by a cutting knife, a cutting direction is perpendicular to a surface of the conductive structure 102, and the groove structure 301 is located at a top end, which faces away from the conductive structure 102, of the hollow rectangular structure 108b, to provide a segmentation mark for the cutting knife, thereby reducing difficulty in segmenting the hollow rectangular structure 108b, the plastic packaging layer 110, and the conductive structure 102.

It should be noted that, the groove structure 301 has an extension direction, and the extension direction of the groove structure 301 is the same as the extension direction of the through-hole 109. In addition, the groove structure 301 does not run through the side wall of the hollow rectangular structure 108b in the extension direction of the groove structure. In a subsequent process of forming the plastic packaging layer 110, the groove structure 301 is not filled with the plastic packaging layer 110. In another embodiment, there may alternatively be a plurality of spaced groove structures.

The groove structure 301 provides a segmentation mark, thereby reducing difficulty in subsequently segmenting the hollow rectangular structure 108b, the plastic packaging layer 110, and the conductive structure 102.

Specifically, FIG. 11 is a partial enlarged view of a part C of FIG. 10. The step of etching an end surface, which faces away from the conductive structure 102, of the hollow rectangular structure 108b to form a groove structure 301 includes: etching the end surface, which face away from the conductive structure 102, of the hollow rectangular structure 108b, to form a first groove 3011; and etching a partial region of a bottom of the first groove 3011 to form a second groove 3012, where the second groove 3012 and the first groove 3011 form the groove structure 301.

In this embodiment, in the step of etching a partial region of a bottom of the first groove 3011, the second groove 3012 is formed at a center of the bottom of the first groove 3011. In a subsequent packaging process, the hollow rectangular structure 108 is segmented along the second groove 3012. This helps form steps on top end surfaces, which face away from the chip 105, of the connecting posts 111b formed through segmentation. The steps are configured to improve strength of subsequent soldering with another circuit component.

As shown in FIG. 12, in the step of forming the plastic packaging layer 110, the plastic packaging layer 110 fills the groove structure 301.

Referring to FIGS. 13A, 13B, a plurality of package structures are shown in FIG. 13A, and only one package structure in FIG. 13B. The step of segmenting the hollow rectangular structure 108b, the plastic packaging layer 110, and the conductive structure 102 includes: segmenting the hollow rectangular structure 108b, the plastic packaging layer 110, and the conductive structure 102 along the groove structure 301 by a cutting knife.

Specifically, the hollow rectangular structure 108b is segmented into spaced connecting posts 111b, and lateral grooves 114b are formed in side surfaces, which face away from the chip 105, of the connecting post 111b; the conductive structure 102 is segmented into spaced leads 112; and correspondingly, the plastic packaging layer 110 originally located in the through-hole 109 is also segmented, the segmented plastic packaging layers 110 are located in the lateral grooves 114b of the connecting posts 111b, and end surfaces 113, which face away from the chip 105, of the connecting posts 111 are exposed outside the plastic packaging layer 110.

In this embodiment, the step of segmenting the hollow rectangular structure 108 and the conductive structure 102 includes: segmenting the hollow rectangular structure 108 and the conductive structure 102 along the second groove 3012 by a cutting knife.

It should be noted that, after the step of segmentation along the second groove 3012 is performed, tops of end surfaces, which face away from the chip, of the connecting posts 111b formed through segmentation have steps 302 (as shown in FIG. 14, a partial enlarged view of a part B of FIG. 13B is shown). The steps 302 are configured to improve strength of subsequent soldering with another circuit component.

An embodiment of the present invention further provides a package structure. Referring to FIGS. 6A, 6B, Embodiment 1 in which a package structure is implemented according to the present invention is schematically shown.

FIG. 6B shows a package structure. The package structure includes: a base island 101; leads 112 spaced apart around the base island 101; a chip 105 located on the base island 101 and electrically connected to the leads 112; connecting posts 111 located on the leads 112 and connected to the leads 112, where end surfaces, which face away from the chip 105, of the connecting posts 111 are provided with lateral grooves 114; and a plastic packaging layer 110 covering the chip 105, the leads 112, and the base island 101, where the plastic packaging layer 110 is filled between the connecting posts 111 and in the lateral grooves 114, and the plastic packaging layer 110 further exposes tops 115 of the connecting posts 111 and the end surfaces 113, which face away from the chip 105, of the connecting posts 111.

In the package structure according to the embodiment of the present invention, the leads 112 are spaced apart around the base island 101. The connecting posts 111 are located on the leads 112 and are connected to the leads 112, and the end surfaces 113, which face away from the chip 105, of the connecting posts 111 are provided with lateral grooves 114. The plastic packaging layer 110 is filled between the connecting posts 111 and in the lateral grooves 114, and the plastic packaging layer 110 further exposes the end surfaces 113, which face away from the chip 105, of the connecting posts 111. Through the end surfaces 113, which are exposed from the plastic packaging layer 110, of the connecting posts 111, the package structure can be electrically connected to another circuit component from a side surface, thereby providing various connection forms. In addition, because the connecting posts 111 are located on the leads 112 and are connected to the leads 112, and the plastic packaging layer 110 further expose the end surfaces 113, which face away from the chip 105, of the connecting posts 111, heat from the leads 112 can be transmitted out through the end surfaces 113 of the connecting posts 111. Compared with a package structure in which heat is dissipated only through a base island 101, the package structure according to an embodiment of the present invention increases a heat dissipation path through the end surfaces 113 of the connecting posts 111, thereby improving a heat dissipation capability of the package structure.

The plastic packaging layer 110 further exposes tops 115 of the connecting posts 111, thereby facilitating an electrical connection between the package structure and another circuit component through the tops 115 of the connecting posts 111 in a subsequent process. In addition, the tops 115 of the connecting posts 111 and the base island 101 are exposed from two opposite surfaces of the plastic packaging layer 110 respectively, so that the base island can dissipate heat upward by mounting the tops 115 of the connecting posts 111 on a PCB subsequently. Furthermore, a heat sink may be arranged on the base island to further improve the heat dissipation capability of the base island.

A cross section of the base island 101 is trapezoidal, and each of the leads 112 is invertedly trapezoidal.

In this embodiment, the package structure is in a form of a quad flat no-lead (QFN) package. The base island 101 has good heat dissipation performance, and the leads 112 have good electrical conductivity.

In this embodiment, the base island 101 and the leads 112 are made of the same material, which includes, but is not limited to, one or more of gold, copper, nickel, and tin.

In this embodiment, a cross section of the base island 101 is rectangular, and a cross section of each of the conductive structures 102 is rectangular. In another embodiment, a cross section of the base island may alternatively be trapezoidal, and a cross section of each of the conductive structures may be invertedly trapezoidal.

The package structure has component regions A. The component regions A each include a first region I and second regions II located around the first region I. The base island 101 is located in the first region I, and the leads 112 are located in the second regions II.

In this embodiment, the first region I is located at a center of the component region A. In another embodiment, the first region I may alternatively be biased to be located on a side of the component region A according to different process layouts.

A chip 105 is attached to the base island 101, so that during operation of the package structure, heat generated by the chip 105 is dissipated out through the base island 101, to reduce a temperature of the chip 105, so that the chip 105 operates normally.

In this embodiment, the chip 105 is attached to the base island 101 by an adhesive film 106. The adhesive film 106 includes a die bonding film. The die bonding film has good adhesion, and can simplify a packaging process and improve manufacturing efficiency. In another embodiment, the chip may alternatively be formed on the base island by a surface mount technology (SMT).

In this embodiment, an electrical connection end of the chip 105 is located at a top of the chip 105. In another embodiment, the electrical connection end of the chip may alternatively be located on a side wall of the chip.

The package structure further includes: wires 107 for connecting the chip 105 to the leads 112.

The wires 107 are configured to electrically connect the chip 105 to the conductive structures 102.

In this embodiment, the wires 107 each are a conductive wire, and the wires 107 are made of a material including gold, copper, or aluminum. Correspondingly, the wires 107 each may be a gold wire, a copper wire, or an aluminum wire.

Because an electrical connection end of the chip 105 is located at the top of the chip 105, correspondingly, the wires 107 electrically connects the conductive structures 102 to the electrical connection end of the top of the chip 105. In another embodiment, because an electrical connection end of the chip is located on a side wall of the chip, the wires electrically connect the conductive structures to the electrical connection end of the side wall of the chip.

In this embodiment, the end portion of the conductive structure 102 is close to the chip 105, so that the wires 107 each have a small length, which reduces parasitic resistance between the leads 112 and the chip 105.

In this embodiment, a through-hole 109 is formed in each of the hollow rectangular structures 108, and the through-hole 109 runs through two corresponding end surfaces of the hollow rectangular structure 108.

In this embodiment, the hollow rectangular structures 108 and the conductive structures 102 are segmented in the same step. Therefore, the end surfaces 113, which face away from the chip 105, of the connecting posts are flush with side walls of the leads 112 in a vertical direction.

It should be noted that, the connecting posts 111 each have a wall thickness greater than 0.1 mm. End surfaces 113, which face away from the chip 105, of the connecting posts 111 each are configured to be connected to another circuit component or to dissipate heat. The wall thicknesses of the connecting posts 111 directly determine areas of the end surfaces 113, which face away from the chip 105, of the connecting posts 111. In this case, if the connecting posts 111 each have a smaller wall thickness, the end surfaces, which face away from the chip 105, of the connecting posts 111 have a poor heat dissipation effect, and the end surfaces, which face away from the chip 105, of the connecting posts each have large contact resistance with another circuit component.

Referring to FIGS. 13A, 13B and FIG. 14, Embodiment 2 in which a package structure is implemented according to the present invention is schematically shown.

Similarities between this embodiment of the present invention and Embodiment 1 are not repeated herein, but differences are as follows.

The package structure further includes: a step 302 located at a top of an end surface 113, which faces away from the chip 105, of each of the connecting posts 111. The step 302 is configured to improve strength of subsequent soldering with another circuit component.

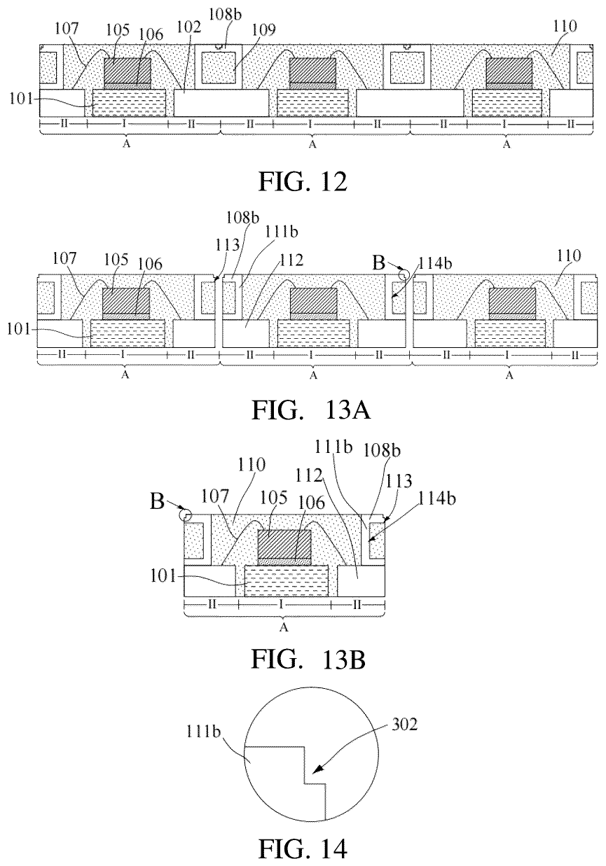

An embodiment of the present invention further provides a stacked package structure. FIG. 15 and FIG. 16 schematically show Embodiment 1 in which a stacked package structure is implemented according to the present invention.

The stacked package structure includes: at least two package structures arranged in a stacked manner, where one or more of the package structures each are the package structure of Embodiment 1 or the package structure of Embodiment 2. The stacking arrangement of the package structures saves space, reduces a mounting area, and improves integration.

In this embodiment, the package structures in the stacked package structure each are the package structure of Embodiment 1 shown in FIG. 6B. A plurality of package structures of Embodiment 1 are stacked, and connecting posts 111 in different package structures are connected.

The end surfaces 113 of the connecting posts 111 are exposed from a side wall of the stacked package structure, thereby improving diversity of electrical connection.

It should be noted that, FIG. 15 shows only a case in which chips 105 in adjacent package structures of Embodiment 1 are arranged opposite each other, and bases of the two package structures are exposed outside the plastic packaging layers, so that the stacked package structure has a good heat dissipation effect. FIG. 16 shows only a case in which chips 105 in adjacent package structures of Embodiment 1 face away each other.

In another embodiment, package structures in the stacked package structure each are the package structure of Embodiment 2 (as shown in FIG. 13B). A plurality of package structures of Embodiment 2 are stacked, and connecting posts in different package structures are connected.

In some other embodiments, the stacked package structure includes both the package structure of Embodiment 1 and the package structure of Embodiment 2. The package structure of Embodiment 1 and the package structure of Embodiment 2 are stacked, and connecting posts in different package structures are connected.

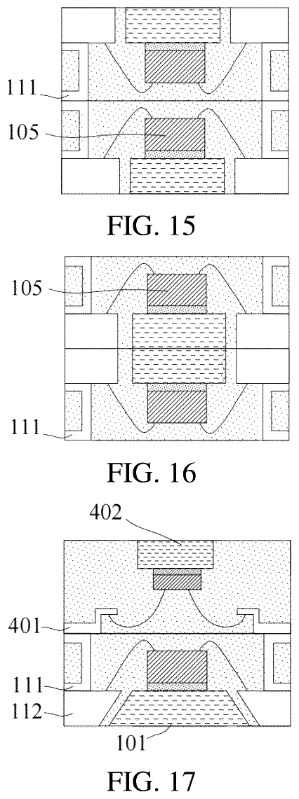

FIG. 17 schematically shows Embodiment 2 in which a stacked package structure is implemented according to the present invention.

The stacked package structure includes: a first package structure, where the first package structure is the package structure of Embodiment 1 or the package structure of Embodiment 2; and a second package structure, where the second package structure is different from the first package structure, and the second package structure includes: conductive pads 401, where conductive pads 401 are connected to connecting posts 111 in a first package structure.

As shown in FIG. 17, the base island 101 in the first package structure is trapezoidal, and the leads 112 are invertedly trapezoidal. In another embodiment, the base island and the leads in the first package structure may alternatively be all rectangular.

In the second package structure, the leads 401 and the base island 402 are positioned on two surfaces of the second package structure that face away from each other.

The package structure may be formed by the forming method in the aforementioned embodiment, or may be formed by another forming method. For a detailed description of the package structure described in this embodiment, reference may be made to the corresponding description in the aforementioned embodiment, and details are not repeated herein.

Although the present invention is disclosed above, the present invention is not limited thereto. A person skilled in the art can make various changes and modifications without departing from the spirit and the scope of the present invention. Therefore, the protection scope of the present invention should be subject to the scope defined by the claims.

What is claimed is:

1. A package structure, comprising:
a base island;
leads spaced apart around the base island;
a chip located on the base island and electrically connected to the leads;
connecting posts located on the leads and connected to the leads, end surfaces, which face away from the chip, of the connecting posts being provided with lateral grooves; and
a plastic packaging layer covering the chip, the leads, and the base island, the plastic packaging layer being filled between the connecting posts and in the lateral grooves, and the plastic packaging layer further exposing tops of the connecting posts and the end surfaces, which face away from the chip, of the connecting posts.

2. The package structure according to claim 1, wherein the end surfaces, which face away from the chip, of the connecting posts are flush with side walls of the leads in a vertical direction.

3. The package structure according to claim 1, wherein tops of the end surfaces, which face away from the chip, of the connecting posts each have a step.

4. The package structure according to claim 1, wherein a cross section of the base island is trapezoidal, and each of the leads is invertedly trapezoidal.

5. The package structure according to claim 1, further comprising:
wires for connecting the chip to the leads.

6. A stacked package structure, comprising:
at least two package structures arranged in a stacked manner, wherein at least a first one of the at least two package structures is the package structure according to claim 1.

7. The stacked package structure according to claim 6, wherein all the package structures are the same as the first one of the package structures and connecting posts in different package structures are connected.

8. The stacked package structure according to claim 6, wherein:
a second one of the at least two package structures is different from the first one of the package structures, the second one of the package structures comprising exposed leads connected to the connecting posts in the first one of the package structures.

9. A packaging method, comprising:
providing a frame, the frame comprising a base island, and conductive structures spaced apart around the base island;
attaching a chip to the base island;
providing hollow rectangular structures, a through-hole being formed in each of the hollow rectangular structures;
attaching each of the hollow rectangular structures to one conductive structure;
forming a plastic packaging layer covering the chip, the base island, and the conductive structures, the plastic packaging layer being further filled between the hollow rectangular structures and in the through-holes of the hollow rectangular structures; and
segmenting the hollow rectangular structure, the plastic packaging layer, and the conductive structure at the through-hole, to form spaced leads and connecting posts located on the leads, lateral grooves being formed in side surfaces, which face away from the chip, of the connecting posts, and the plastic packaging layer being filled in the lateral grooves and exposing tops of the connecting posts and end surfaces, which face away from the chip, of the connecting posts.

10. The packaging method according to claim 9, wherein each of the hollow rectangular structures is attached to one conductive structure by a metal bonding process, a surface mount technology, or an adhesive process.

11. The packaging method according to claim 9, wherein the step of providing hollow rectangular structures comprises:
manufacturing a stamping mold; providing a metal sheet; placing the metal sheet in the stamping mold; and stamping the metal sheet to form the hollow rectangular structures,
or the step of providing hollow rectangular structures comprises: providing a cuboid structure, the cuboid structure being made of a metal; and etching the cuboid structure by a dry etching process, to form the hollow rectangular structures.

12. The packaging method according to claim 9, wherein the step of segmenting the hollow rectangular structure and the conductive structure comprises:
segmenting the hollow rectangular structure and the conductive structure by a cutting knife, a laser, or a plasma etching process.

13. The packaging method according to claim 9, wherein in the step of segmenting the hollow rectangular structure and the conductive structure, the end surfaces, which face away from the chip, of the connecting posts are flush with side walls of the leads in a vertical direction.

14. The packaging method according to claim 9, wherein in the step of providing hollow rectangular structures, each of the hollow rectangular structures has an opening in communication with one through-hole;
in the step of attaching each of the hollow rectangular structures to one conductive structure, the opening is located at an end, which faces away from the conductive structure, of the hollow rectangular structure; and
the step of segmenting the hollow rectangular structure, the plastic packaging layer, and the conductive structure comprises: segmenting the hollow rectangular structure, the plastic packaging layer, and the conductive structure along the opening by a cutting knife, a laser, or a plasma etching process.

15. The packaging method according to claim 9, further comprising: etching, after the attaching each of the hollow rectangular structures to one conductive structure, an end surface, which face away from the conductive structure, of the hollow rectangular structure, to form a non-through groove structure; and
the step of segmenting the hollow rectangular structure, the plastic packaging layer, and the conductive structure comprises: segmenting the hollow rectangular structure and the conductive structure along the groove structure by a cutting knife, a laser, or a plasma etching process.

16. The packaging method according to claim 15, wherein the step of etching an end surface, which face away from the conductive structure, of the hollow rectangular structure, to form a non-through groove structure comprises:
etching the end surface, which face away from the conductive structure, of the hollow rectangular structure, to form a non-through first groove; and
etching a partial region of a bottom of the first groove to form a second groove, the second groove and the first groove forming the groove structure; and
the step of segmenting the hollow rectangular structure, the plastic packaging layer, and the conductive structure comprises: segmenting the hollow rectangular structure, the plastic packaging layer, and the conductive structure along the second groove by a cutting knife, a laser, or a plasma etching process, and forming steps at tops of the end surfaces, which face away from the chip, of the connecting posts.

17. The packaging method according to claim 16, wherein in the step of etching a partial region of a bottom of the first groove, the second groove is formed at a center of the bottom of the first groove.

18. The packaging method according to claim 9, wherein in the step of segmenting the hollow rectangular structure, the plastic packaging layer, and the conductive structure, segmentation is performed along a center of the hollow rectangular structure.

19. The packaging method according to claim 9, wherein the step of forming a plastic packaging layer covering the chip, the base island, the conductive structures, and the hollow rectangular structures comprises: forming a plastic packaging material layer covering the chip, the base island, the conductive structures, and the hollow rectangular structures; and planarizing the plastic packaging material layer, with tops of the hollow rectangular structures as planarization positions, to form the plastic packaging layer.

20. The packaging method according to claim 9, wherein in the step of providing a frame, a cross section of the base island is trapezoidal, and each of the conductive structures is invertedly trapezoidal; and
each of the leads is invertedly trapezoidal after the hollow rectangular structure, the plastic packaging layer, and the conductive structure are segmented.
